(19) United States
(12) Patent Application Publication
(10) Pub. No.: US 2026/0020395 A1
(43) Pub. Date: Jan. 15, 2026

(54) LIGHT-EMITTING DEVICE AND METHOD OF MANUFACTURING LIGHT-EMITTING DEVICE

(71) Applicant: NICHIA CORPORATION, Anan-shi (JP)

(72) Inventor: Shinichi DAIKOKU, Tokushima-shi (JP)

(73) Assignee: NICHIA CORPORATION, Anan-shi (JP)

(21) Appl. No.: 19/116,153

(22) PCT Filed: Sep. 27, 2023
(86) PCT No.: PCT/JP2023/035195

§ 371 Date: Mar. 27, 2025

(30) Foreign Application Priority Data
Sep. 28, 2022 (JP) 2022-155156
Sep. 15, 2023 (JP) 2023-150299

(51) Int. Cl. H10H 20/856; H10H 20/01

(52) U.S. Cl. CPC H10H 20/856; H10H 20/0363

(57) ABSTRACT

A light-emitting device of the present disclosure includes: a light-emitting element including a semiconductor structure having a light-emitting surface, an electrode-forming surface located on a side opposite to the light-emitting surface, and a lateral surface located between the light-emitting surface and the electrode-forming surface, and a first electrode disposed on the electrode-forming surface and having a first surface facing the electrode-forming surface, a second surface located on a side opposite to the first surface, and a lateral surface located between the first surface and the second surface; and a light-reflective member configured to cover the light-emitting element except for the light-emitting surface and the second surface, wherein the light-reflective member includes: a light-reflective inorganic member covering at least a lateral surface of the semiconductor structure; and a light-reflective resin member covering a lateral surface of the first electrode and the light-reflective inorganic member.

### CROSS-REFERENCE TO RELATED APPLICATION

This is a national stage of PCT Application No. PCT/JP2023/035195, filed on Sep. 27, 2023, which claims priority to Japanese Patent Application No. 2022-155156, filed on Sep. 28, 2022 and Japanese Patent Application No. 2023-150299 filed on Sep. 15, 2023.

### TECHNICAL FIELD

The present disclosure relates to a light-emitting device and a method of manufacturing a light-emitting device.

### BACKGROUND

In recent years, a light source that uses a light-emitting element such as a light-emitting diode has been widely used. For example, Japanese Patent Publication No. 2018-14480 discloses a light-emitting device in which at least a lateral surface of a light-emitting element is covered with a light-reflective covering member, and a phosphor layer is disposed on an upper surface of the light-emitting element.

### SUMMARY

However, there is still room for improvement in the light-reflective covering member in order to improve the performance of the light-emitting device. As an example, a covering member that covers a light-emitting element generates heat when irradiated with light from the light-emitting element, and therefore further improvement in heat resistance has been needed.

Accordingly, an object of the present disclosure is to provide a light-emitting device including a covering member having a higher heat resistance, and a method of manufacturing the light-emitting device.

### Solution to Problem

A light-emitting device according to the present disclosure includes:

a light-emitting element including a semiconductor structure having a light-emitting surface, an electrode-forming surface located on a side opposite to the light-emitting surface, and a lateral surface located between the light-emitting surface and the electrode-forming surface, and a first electrode disposed on the electrode-forming surface and having a first surface facing the electrode-forming surface, a second surface located on a side opposite to the first surface, and a lateral surface located between the first surface and the second surface; and a light-reflective member covering the light-emitting element except for the light-emitting surface and the second surface, wherein the light-reflective member comprises:
a light-reflective inorganic member covering at least a lateral surface of the semiconductor structure; and
a light-reflective resin member covering a lateral surface of the first electrode, and the light-reflective inorganic member.

A method of manufacturing a light-emitting device according to the present disclosure includes:
a preparing step of preparing a light-emitting element including a semiconductor structure having a light-emitting surface and an electrode-forming surface located on a side opposite to the light-emitting surface, and a first electrode disposed on the electrode-forming surface and having a first surface facing the electrode-forming surface, a second surface located on a side opposite to the first surface, and a lateral surface located between the first surface and the second surface;
a first covering step of covering a lateral surface of the light-emitting element with a light-reflective inorganic member; and
a second covering step of covering the electrode-forming surface with a light-reflective resin member to expose the second surface.

### Advantageous Effects of Invention

According to the present disclosure, it is possible to provide a light-emitting device including a covering member having a higher heat resistance, and a method of manufacturing the light-emitting device.

### BRIEF DESCRIPTION OF DRAWINGS

FIG. 1A is a schematic perspective view of a light-emitting device according to a first embodiment of the present disclosure as viewed obliquely from above.

FIG. 1B is a schematic perspective view of the light-emitting device according to the first embodiment of the present disclosure as viewed obliquely from below.

FIG. 2 is a schematic cross-sectional view of the light-emitting device according to the first embodiment of the present disclosure.

FIG. 3A is a schematic perspective view of a light-emitting device according to a second embodiment of the present disclosure as viewed obliquely from above.

FIG. 3B is a schematic perspective view of a light-emitting device according to the second embodiment of the present disclosure as viewed obliquely from below.

FIG. 4 is a schematic cross-sectional view of the light-emitting device according to the second embodiment of the present disclosure.

FIG. 5 is a schematic cross-sectional view of a light-emitting device according to a third embodiment of the present disclosure.

FIG. 6 is a schematic cross-sectional view of a modified example of the light-emitting device of the present disclosure.

FIG. 7A is a schematic plan view of another modified example of the light-emitting device of the present disclosure.

FIG. 7B is a schematic plan view of another modified example of the light-emitting device of the present disclosure.

FIG. 8 is a schematic cross-sectional view of a light-emitting device according to a fourth embodiment of the present disclosure.

FIG. 9 is a schematic cross-sectional view of a modified example of the light-emitting device according to the fourth embodiment of the present disclosure.

FIG. 10 is a schematic cross-sectional view illustrating a method of manufacturing a light-emitting device of the present disclosure.

FIG. 11 is a schematic cross-sectional view illustrating the method of manufacturing a light-emitting device of the present disclosure.

FIG. 12 is a schematic cross-sectional view illustrating the method of manufacturing a light-emitting device of the present disclosure.

FIG. 13 is a schematic cross-sectional view illustrating the method of manufacturing a light-emitting device of the present disclosure.

FIG. 14 is a schematic cross-sectional view illustrating the method of manufacturing a light-emitting device of the present disclosure.

### DESCRIPTION OF EMBODIMENTS

Embodiments of the present disclosure are described below with reference to the drawings. The light-emitting device and the method of manufacturing the light-emitting device described below are intended to embody the technical idea of the present disclosure, and the present disclosure is not limited to the following description unless otherwise specified.

In each drawing, members having identical functions may be denoted by the same reference characters. For ease of explanation or understanding of the points of view, the plurality of exemplary embodiments and examples may be illustrated separately for convenience, but partial substitutions or combinations of the constituent components illustrated in different embodiments and examples are possible. In the embodiments and examples described below, descriptions of matters common to those already described will be omitted, and only different features will be described. In particular, the same or similar effects of the same or similar configurations shall not be mentioned each time for individual embodiments. The sizes, positional relationship, and the like of members illustrated in the drawings may be exaggerated in order to clarify explanation. As a cross-sectional view, an end view illustrating only a cut surface may be used.

Embodiment of Light-emitting Device

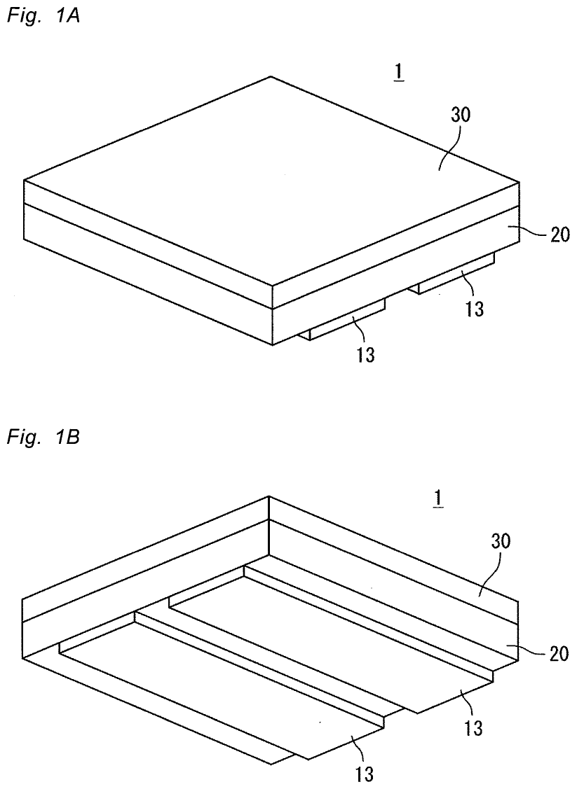

A light-emitting device 1 according to an embodiment of the present disclosure will be described in detail with reference to FIGS. 1A to 3B. The light-emitting device 1 according to an embodiment of the present disclosure includes at least a light-emitting element 10 and a light-reflective member 20.

The light-emitting element 10 includes a semiconductor structure 11 and a first electrode 12. The semiconductor structure 11 has a light-emitting surface 11a, an electrode-forming surface 11b opposite to the light-emitting surface 11a, and a lateral surface 11c between the light-emitting surface 11a and the electrode-forming surface 11b. The first electrode 12 is disposed on the electrode-forming surface 11b, and has a first surface 12a facing the electrode-forming surface 11b, a second surface 12b located on a side opposite to the first surface 12a, and a lateral surface 12c located between the first surface 12a and the second surface 12b.

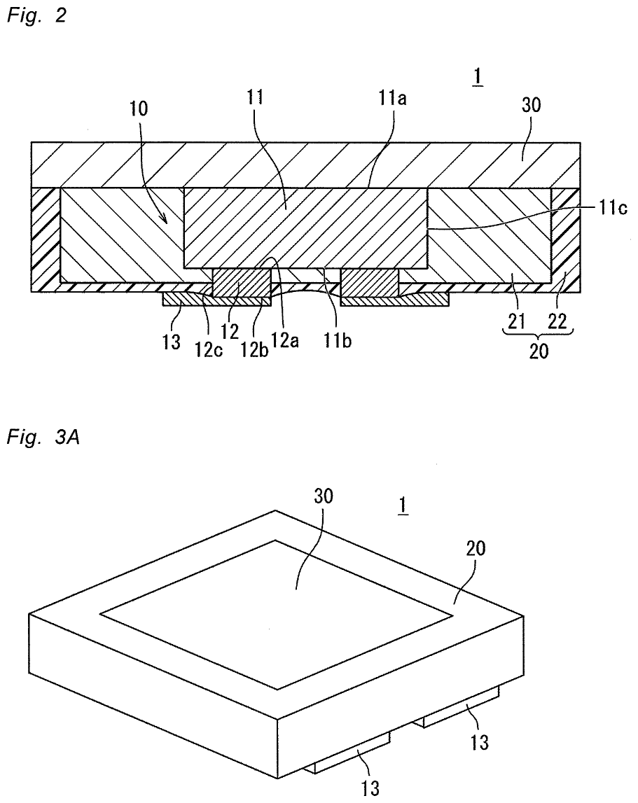

The light-reflective member 20 covers the light-emitting element 10 except for the light-emitting surface 11a and the second surface 12b. The light-reflective member 20 includes a light-reflective inorganic member 21 covering at least the lateral surface 11c of the semiconductor structure 11, and a light-reflective resin member 22 covering the lateral surface 12c of the first electrode 12 and the light-reflective inorganic member 21. Hereinafter, components of the light-emitting device 1 according to the first embodiment of the present disclosure will be described in detail with reference to FIGS. 1A, 1B, and 2.

### FIRST EMBODIMENT

### Light-emitting Element

As the light-emitting element 10, for example, a semiconductor light-emitting element such as a light-emitting diode can be used, and the light-emitting element 10 that can emit visible light of blue, green, red, or the like can be used. The light-emitting device illustrated in FIGS. 1A, 1B, and 2 includes one light-emitting element 10. The light-emitting element 10 includes a semiconductor structure 11 including a light-emitting layer, and the first electrode 12. The semiconductor structure 11 has a surface on which the first electrode 12 is formed (electrode-forming surface) and a light extraction surface (light-emitting surface) opposite to the electrode-forming surface.

The semiconductor structure 11 includes a semiconductor layer including a light-emitting layer. Further, a light-transmissive substrate such as sapphire may be provided on the light-emitting surface 11a side of the semiconductor structure 11. As an example, the semiconductor structure 11 may include three semiconductor layers of a first conductivity type semiconductor layer (for example, an n-type semiconductor layer), a light-emitting layer (active layer), and a second conductivity type semiconductor layer (for example, a p-type semiconductor layer). The semiconductor layer that can emit ultraviolet light or visible light from blue light to green light can be formed of, for example, a semiconductor material such as a group III-V compound semiconductor. Specifically, a nitride-based semiconductor material such as In_{X}Al_{Y}Ga_{1-X-Y}N (0≤X, 0≤Y, X+Y≤1) can be used. As a semiconductor layered body that can emit red light, GaAs, GaAlAs, GaP, InGaAs, InGaAsP, or the like can be used. The peak wavelengths of the light emitted from the semiconductor structure 11 may be, for example, in a range from 260 nm to 630 nm.

The first electrodes 12 include, for example, a negative electrode and a positive electrode, and is disposed on the same surface side (electrode-forming surface) of the semiconductor structure 11. The first electrode 12 has the first surface 12a facing the electrode-forming surface 11b of the semiconductor structure 11, the second surface 12b opposite to the first surface 12a, and the lateral surface 12c between the first surface 12a and the second surface 12b. The pair of first electrodes 12 may have a single-layer structure or a layered structure. Such a first electrode 12 can be formed with an discretionary thickness using a material and a configuration known in the art. For example, it is preferable for the thickness of the first electrode 12 to be in a range from ten and several um to 300 μm. In addition, as the first electrode 12, a good conductor can be used, and for example, a conductor containing one or more metals selected from the group consisting of Au, Pt, Pd, Rh, Ni, W, Mo, Cr, Ti, Al, Cu, Sn, Fe, and Ag is suitable. As the shape of the electrode, various shapes can be selected according to the purpose, application, and the like.

### Light-reflective Inorganic Member

The light-reflective inorganic member 21 reflects light emitted from the light-emitting element 10. The light-reflective inorganic member 21 can reflect light from the light-emitting element 10 at a reflectance of 70% or more, for example. The light-reflective inorganic member 21 is a member formed of an inorganic material. The light-reflective inorganic member 21 includes, for example, a filler of an inorganic material and a support material that supports the filler. The filler of an inorganic material is, for example, plate-like particles. Examples of the filler of an inorganic material include at least one selected from boron nitride, silicon nitride, aluminum nitride, and aluminum oxide. The filler may function as an aggregate. Accordingly, even when the temperature of the light-reflective inorganic member 21 changes, deformation of the light-reflective inorganic member 21 can be suppressed. The filler can also reflect light from the light-emitting element.

By supporting the filler with the support material, the light-reflective inorganic member can be formed into a desired shape. An example of the support material is a mixture of potassium hydroxide and at least one selected from aluminum oxide, titanium oxide, and silicon oxide. The potassium hydroxide contained in the support material is mixed with an aqueous solution of potassium hydroxide, and voids are formed inside the light-reflective inorganic member 21 by evaporation of moisture contained in the aqueous solution. Here, when a material different from the filler is used as the support material, the filler and the support material are preferably contained so that the weight of the filler is in a range from 1time to 4 times the weight of the support material. Within this range, shrinkage of the mixture during curing can be reduced. Further, the average particle size of the support material is preferably smaller than the average particle size of the filler. With such a particle size, voids formed between the fillers at the time of mixing can be filled with the support material. The average particle size of the support material can be calculated by measuring the particle size distribution with a laser diffraction method.

The above-mentioned filler and support material may contain an alkali metal. One example of an alkali metal is potassium and/or sodium.

The light-reflective inorganic member 21 may further contain a light-scattering material. The light-scattering material is, for example, mainly zirconium oxide, titanium oxide, or silicon oxide. In the case in which the light-emitting element emits ultraviolet light, zirconium oxide, which absorbs less light in the ultraviolet wavelength region, is desirable. When the light-reflective inorganic member 21 contains a light-scattering material, the light reflectance of the light-reflective inorganic member 21 is improved. As a result, the luminance difference between the light-emitting surface of the light-emitting device 1 and the light-reflective inorganic member (non-light-emitting surface) surrounding the light-emitting surface becomes sharp. That is, the contrast on the light-emitting surface 11a side of the light-emitting device 1 is improved. As used herein, the term “contrast” refers to the difference in luminance between the light-emitting surface and the non-light-emitting surface. As the light-scattering material, titanium oxide alone may be used, or titanium oxide whose surface is covered with a coating film formed of one or more of silica, aluminum oxide, zirconium oxide, zinc, an organic material, and the like may be used. As the light-scattering material, zirconium oxide alone may be used, or zirconium oxide whose surface is covered with a coating film formed of one or more of silica, aluminum oxide, zinc, an organic material, and the like may be used. Alternatively, stabilized zirconium oxide to which calcium, magnesium, yttrium, aluminum, or the like is added, or partially stabilized zirconium oxide may be used.

The outer shape of the light-reflective inorganic member 21 in a top view may be, for example, a quadrilateral such as a square or a rectangle, or a polygon such as a triangle or a pentagon. In the example illustrated in FIG. 1A, the outer shape of the light-reflective resin member 22 is a square.

The light-reflective inorganic member 21 covers the semiconductor structure 11 except for the light-emitting surface of the semiconductor structure 11 and the region where the first electrode 12 is disposed. To be more specific, the light-reflective inorganic member 21 covers the lateral surface 11c of the semiconductor structure 11 and the region of the electrode-forming surface 11b other than the region where the first electrode 12 is disposed. As used herein, the term “cover” includes an aspect in which the light-reflective inorganic member 21 is in contact with and directly covers the semiconductor structure 11, and an aspect in which the light-reflective inorganic member 21 is not in contact with the semiconductor structure 11 and indirectly covers the semiconductor structure 11 via another member or a space (for example, an air layer). The light-reflective inorganic member 21 further covers the lateral surface of the first electrode 12. However, the second surface 12b of the first electrode 12 is not covered with the light-reflective inorganic member 21 because a second electrode 13, which will be described below, is disposed thereon.

In general, an inorganic material has a relatively high melting point and a good heat resistance. Therefore, according to such a light-emitting device 1, because at least the lateral surface 11c of the semiconductor structure 11 is covered with the light-reflective inorganic member 21 having a good heat resistance, the heat resistance characteristics can be improved. In addition, because in general, an inorganic material has a higher thermal conductivity than an organic material and has good heat dissipation characteristics, heat can be appropriately released toward the outside of the light-reflective inorganic member 21 (for example, toward a light-reflective resin member 22 or the wavelength conversion member 30 described below).

### Light-reflective Resin Member

The light-reflective resin member 22 contains a light-reflective substance. The light-reflective resin member 22 can reflect light from the light-emitting element 10 at a reflectance of 70% or more, for example. As an example of the light-reflective resin member 22, a thermosetting resin is preferable, and examples thereof include a silicone resin, a silicone-modified resin, an epoxy resin, and/or a phenol resin. When the main component of the light-reflective resin member 22 is a resin, the light-reflective resin member 22 may contain a light-reflective substance. For example, titanium oxide, silicon oxide, zirconium oxide, potassium titanate, aluminum oxide, aluminum nitride, boron nitride, or mullite may be contained as the light-reflective substance. The light-reflective substance may be in the grain-like, fiber-like, or flake-like shape, or the like, but is particularly preferably in the fiber-like shape because the effect of reducing the coefficient of thermal expansion of the covering member can be expected.

The light-reflective resin member 22 formed of the above-described material indirectly covers the semiconductor structure 11 except for the light-emitting surface of the semiconductor structure 11. In other words, the light-reflective resin member 22 covers the light-reflective inorganic member 21 covering the semiconductor structure 11. More specifically, the light-reflective resin member 22 entirely covers the outer surface of the light-reflective inorganic member 21 except for the surface facing the wavelength conversion member 30 described below. As used herein, the “outer surface of the light-reflective inorganic member 21” refers to the surface(s) of the light-reflective inorganic member 21 excluding the surface(s) facing the light-emitting element 10 and the surface facing the wavelength conversion member 30.

By covering the light-reflective inorganic member 21 with the light-reflective resin member 22 in this manner, even when the light-reflective resin member is processed in the “electrode exposing step” described below in the method of manufacturing a light-emitting device, damage to the light-reflective inorganic member due to the processing can be reduced.

In a preferred aspect of the light-reflective resin member 22, the thickness of the light-reflective resin member 22 located on the electrode-forming surface 11b side of the semiconductor structure 11 may increase toward the first electrode 12. The reason for this is that the light-reflective resin member 22 is pressed and deformed by a grindstone when the light-reflective resin member 22 is ground, which will be described in detail in “Method of Manufacturing Light-emitting Device” below.

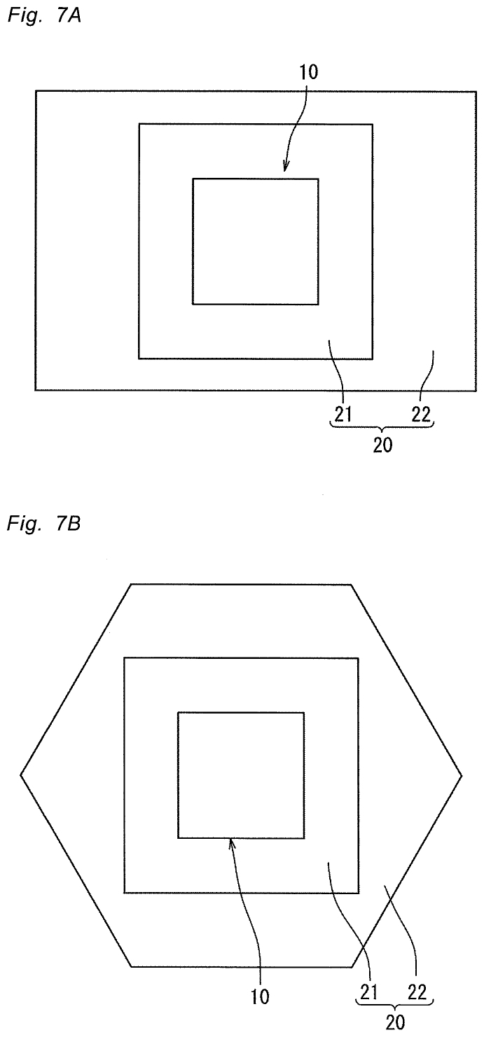

The outer shape of the light-reflective resin member 22 in a top view can be, for example, a quadrilateral such as a square or a rectangle, or a polygon such as a triangle or a pentagon. In the examples illustrated in FIGS. 1A, 1B, and 2, the outer shape of the light-reflective resin member 22 in a top view is a square. In the example illustrated in FIG. 7A, the shapes of the light-reflective inorganic member 21 and the light-reflective resin member 22 in a top view are different. In this example, the light-emitting element 10 and the light-reflective inorganic member 21 have a square outer shape in a top view, and the light-reflective resin member 22 has a rectangular outer shape in a top view. The shapes of the light-emitting element 10 and the light-reflective inorganic member 21 are not limited to the above-described shapes, and the shapes of the light-reflective inorganic member 21 and the light-reflective resin member 22 in a top view may be different polygonal shapes or the like. For example, as illustrated in FIG. 7B, the light-emitting element 10 and the light-reflective inorganic member 21 may have a square outer shape in a top view, and the light-reflective resin member 22 may have a hexagonal outer shape in a top view.

### Wavelength Conversion Member

In the light-emitting device 1, the wavelength conversion member 30 may be disposed at the light-emitting surface 11a of the light-emitting element 10. Examples of the wavelength conversion substance contained in the wavelength conversion member 30 include an yttrium aluminum garnet-based phosphor (for example, (Y, Gd)₃(Al, Ga)₅O₁₂:Ce), a lutetium aluminum garnet-based phosphor (for example, Lu₃(Al, Ga)₅O₁₂:Ce), a terbium aluminum garnet-based phosphor (for example, Tb₃(Al, Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba, Sr, Ca, Mg)₂SiO₄:Eu), oxynitride-based phosphors, such as a β-SiAlON-based phosphor (for example, (Si, Al)₃(O,N)₄:Eu) and an α-SiAlON-based phosphor (for example, Ca (Si, Al)₁₂(O,N)₁₆:Eu), nitride-based phosphors, such as an LSN-based phosphor (for example, (La, Y)₃Si₆N₁₁:Ce), a BSESN-based phosphor (for example, (Ba, Sr)₂Si₅N₈:Eu), an SLA-based phosphor (for example, SrLiAl₃N₄:Eu), a CASN-based phosphor (for example, CaAlSiN₃: Eu), and an SCASN-based phosphor (for example, (Sr, Ca) AlSiN₃:Eu), fluoride-based phosphors, such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), and an MGF-based phosphor (for example, 3.5 MgO·0.5 MgF₂·GeO₂:Mn), a quantum dot having a perovskite structure (for example, (Cs, FA, MA)(Pb, Sn)(F, Cl, Br, I)₃, where FA and MA represent formamidinium and methylammonium, respectively), a II-VI group quantum dot (for example, CdSe), a III-V group quantum dot (for example, InP), a quantum dot having a chalcopyrite structure (for example, (Ag, Cu)(In, Ga)(S, Se)₂), or the like. The phosphors described above are particles. Further, one type of these wavelength conversion substances can be used alone, or two or more types of these wavelength conversion substances can be used in combination.

Examples of the wavelength conversion member 30 include a resin material, ceramics, glass, or the like containing the wavelength conversion substance, a sintered body, and the like. In addition, the wavelength conversion member 30 may be obtained by disposing a resin material containing a wavelength conversion member on a surface of a molded body of a resin material, ceramics, glass, or the like. The resin material is preferably a light-transmissive resin, and a thermosetting resin such as a silicone resin, a silicone modified resin, an epoxy resin, or a phenol resin, or a thermoplastic resin such as a polycarbonate resin, an acrylic resin, a methylpentene resin, or a polynorbornene resin can be used. In particular, a silicone resin having excellent light resistance and heat resistance is suitable.

When the irradiation light irradiated through the wavelength conversion member 30 is white light, for example, the light-emitting element 10 that emits blue light and the wavelength conversion member 30 that emits yellow light by the light from the light-emitting element 10 can be combined.

The wavelength conversion member 30 may include a light diffusion member that diffuses the excitation light and the wavelength-converted light. The light diffusion member may contain, for example, titanium oxide, barium titanate, aluminum oxide, silicon oxide, or the like.

The lateral surface of the wavelength conversion member 30, which will be described in detail in “Method of Manufacturing Light-emitting Device” below, may be flush with the lateral surface of the light-reflective resin member 22 by singulation to form the outer lateral surface of the light-emitting device 1.

A light-transmissive member that does not contain a wavelength conversion substance can be used as the wavelength conversion member 30. Disposing the light-transmissive member, the light-emitting surface 11a of the light-emitting element 10 can increase light extraction. The light-transmissive member is a member that transmits light emitted from the light-emitting element 10 without wavelength conversion. The light-transmissive member may be, for example, a molded body of a resin material, ceramics, glass, or the like.

The resin material of the light-transmissive member is preferably a light-transmissive resin. Examples of the resin material of the light-transmissive resin include a thermosetting resin such as a silicone resin, a silicone modified resin, an epoxy resin, or a phenol resin, or a thermoplastic resin such as a polycarbonate resin, an acrylic resin, a methylpentene resin, or a polynorbornene resin. In particular, a silicone resin having excellent light resistance and heat resistance is suitable.

The light-transmissive member may include a light diffusion member that diffuses light from the light-emitting element 10. The light diffusion member may include, for example, a light diffusion member that can contain titanium oxide, barium titanate, aluminum oxide, silicon oxide, or the like. By including the light diffusion member, the light diffusibility can be improved.

As illustrated in FIG. 6, a light-transmissive member or a wavelength conversion member does not have to be disposed on the light-emitting surface 11a of the light-emitting element 10. In this case, the upper surface of the light-reflective inorganic member 21 and the light-emitting surface 11a of the light-emitting element 10 constitute the upper surface of the light-emitting device 1. In such a light-emitting device 1, when light-emitting element 10 that can emit ultraviolet light is used as the light-emitting element 10, the light-emitting device 1 can be reduced in size by not disposing a light-transmissive member or a wavelength conversion member on the light-emitting surface 11a side of the light-emitting element 10.

### Second Electrode

The light-emitting device 1 may include the second electrode 13 bonded to the second surface 12b of the first electrode 12. The second electrode 13 may be provided so as to extend from the second surface 12b to the outer surface of the light-reflective resin member 22.

The second electrode 13 mainly functions as an external electrode of the light-emitting device 1. As the material of the second electrode 13, a material having better corrosion resistance and oxidation resistance than those of the first electrode 12 is preferably selected. For example, the outermost surface layer is preferably formed of Au or a platinum group element such as Pt. Considering that the light-emitting device 1 is mounted using solder, it is preferable to use Au, which has good solderability, for the outermost surface of the second electrode 13.

The second electrode 13 may be formed of only a single layer of a single material, or may be formed by stacking layers of different materials. In particular, the second electrode 13 having a high melting point is preferably used, and examples thereof include Ru, Mo, Ta, and the like. In addition, by providing such a metal having a high melting point between the first electrode 12 of the light-emitting element 10 and the outermost surface layer, a diffusion suppression layer that can reduce diffusion of Sn contained in the solder to the first electrode 12 or to a layer close to the first electrode 12 can be formed. Examples of the layered structure having such a diffusion suppression layer include Ni/Ru/Au, Ti/Pt/Au, and the like. The thickness of the diffusion suppression layer (for example, Ru) is preferably about in a range from 10 Å to 1000 Å.

As described above, the light-emitting device 1 according to the first embodiment of the present disclosure includes the light-reflective inorganic member 21 to improve heat resistance, and includes the light-reflective resin member 22 to reduce deformation of the light-reflective inorganic member 21 due to processing during manufacture of the light-emitting device 1. As an example, in the electrode exposing step described below, the light-reflective inorganic member 21 is covered with the light-reflective resin member 22 as illustrated in FIG. 13, so the influence of processing on the light-reflective inorganic member 21 can be reduced. The wavelength conversion member 30 of the present embodiment may be a light-transmissive member that does not contain a wavelength conversion substance. As will be described in detail in the fifth embodiment below, the light-reflective resin member 22 of the present embodiment may be a resin member that transmits light.

### SECOND EMBODIMENT

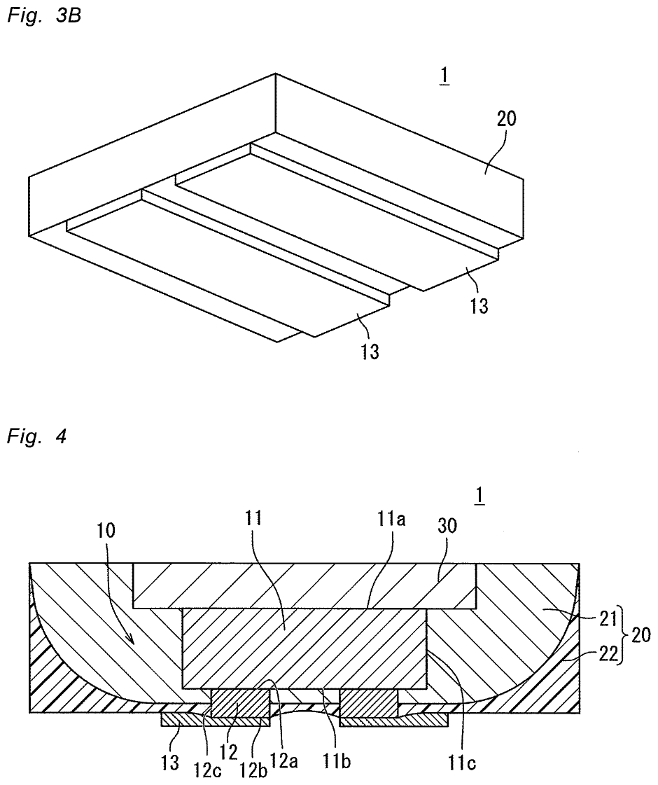

Next, components of the light-emitting device 1 according to a second embodiment of the present disclosure will be described in detail with reference to FIGS. 3A, 3B, and 4. The light-emitting device 1 of the second embodiment differs from the light-emitting device 1 of the first embodiment in the configuration of the light-reflective inorganic member 21 and the light-reflective resin member 22, and the configuration of the wavelength conversion member 30. The other configurations are basically the same as those of the light-emitting device according to the first embodiment of the present disclosure described above. This different configuration will be described below.

Aspects of Light-reflective Inorganic Member and Light-reflective Resin Member In the light-emitting device of the second embodiment, the surface of the light-reflective inorganic member 21 opposite to the surface facing the lateral surface of the light-emitting element 10 is inclined or curved. Specifically, the interface between the light-reflective inorganic member 21 and the light-reflective resin member 22 is inclined or curved. The distance from the lateral surface of the light-emitting element 10 to the interface between the light-reflective inorganic member 21 and the light-reflective resin member 22 increases toward the light-emitting surface 11a.

According to such a configuration, the light-reflective inorganic member 21 having a good heat resistance is disposed so as to become thicker as it gets closer to the light-emitting surface 11a, which is easily heated, whereby the heat resistance can be further improved. In addition, because the inorganic material has good heat dissipation characteristics, heat can be appropriately dissipated to the outside of the light-reflective inorganic member 21.

Aspect of Wavelength Conversion Member

In the light-emitting device 1 according to the second embodiment, the lateral surface of the wavelength conversion member 30 is covered with the light-reflective inorganic member 21. According to such a configuration, the light-reflective inorganic member 21 and the light-reflective resin member 22 can be disposed also on the lateral surface of the wavelength conversion member 30, the volume of the light-reflective inorganic member 21 can be increased as compared with the light-emitting device of the first embodiment, and the heat resistance can be further improved. In addition, heat generated during wavelength conversion in the wavelength conversion member 30 can be appropriately transferred to the light-reflective inorganic member 21. In addition, because the light-reflective resin member 22 is separated from the wavelength conversion member 30, cracking of the light-reflective resin member 22 due to heat generated in the wavelength conversion member 30 can be suppressed.

### THIRD EMBODIMENT

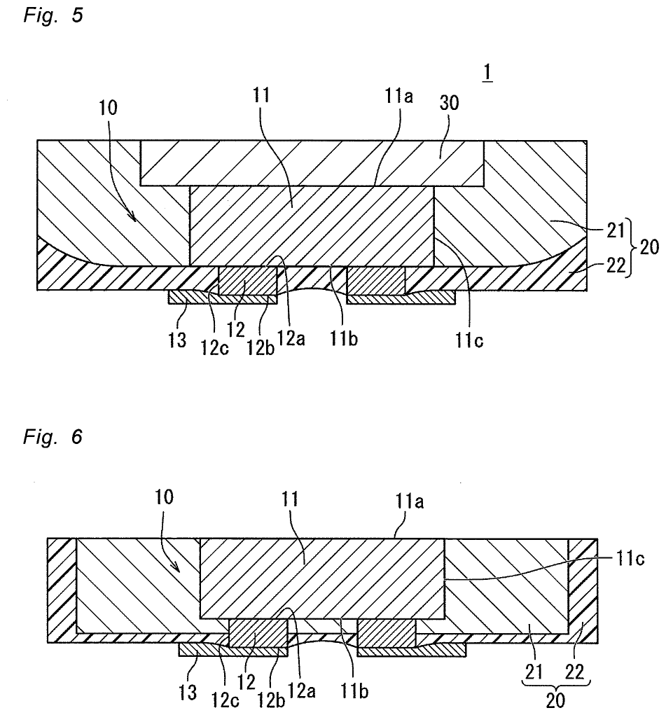

Next, components of the light-emitting device 1 according to a third embodiment of the present disclosure will be described in detail with reference to FIG. 5. The light-emitting device 1 of the third embodiment is different from the light-emitting device 1 of the second embodiment in the manner of covering with the light-reflective inorganic member 21 and the light-reflective resin member 22. The other configurations are basically the same as those of the light-emitting devices according to the first embodiment and the second embodiment of the present disclosure described above. This different configuration will be described below.

Aspects of Light-reflective Inorganic Member and Light-reflective Resin Member In the light-emitting device 1 of the third embodiment, the outer lateral surface of the light-emitting device 1 is constituted by the light-reflective inorganic member 21 and the light-reflective resin member 22. The electrode-forming surface 11b is covered with the light-reflective resin member 22. According to such a configuration, the volume of the light-reflective inorganic member 21 on the electrode-forming surface 11b can be reduced, and therefore, even when the light-reflective resin member 22 is processed in the “electrode exposing step” described below in the method of manufacturing a light-emitting device, deformation of the light-reflective inorganic member 21 due to the processing can be reduced.

### FOURTH EMBODIMENT

Next, the light-emitting device 1 according to a fourth embodiment of the present disclosure will be described. The light-emitting device according to the fourth embodiment is different from the invention according to the first embodiment in that a plurality of light-emitting elements 10 are provided. Other configurations are basically the same as those of the light-emitting devices according to the first to third embodiments of the present disclosure described above, but configurations different from those of the above embodiments will be described in detail below.

### Aspect of Light-emitting Element

As the plurality of light-emitting elements 10, for example, three light-emitting elements 10 of a light-emitting element 10 that emits red light, a light-emitting element 10 that emits blue light, and a light-emitting element 10 that emits green light may be used, or any two of the light-emitting elements 10 may be used. Alternatively, light-emitting elements 10 that emit light of different wavelengths may be used, or light-emitting elements 10 that emit light of the same wavelength may be used.

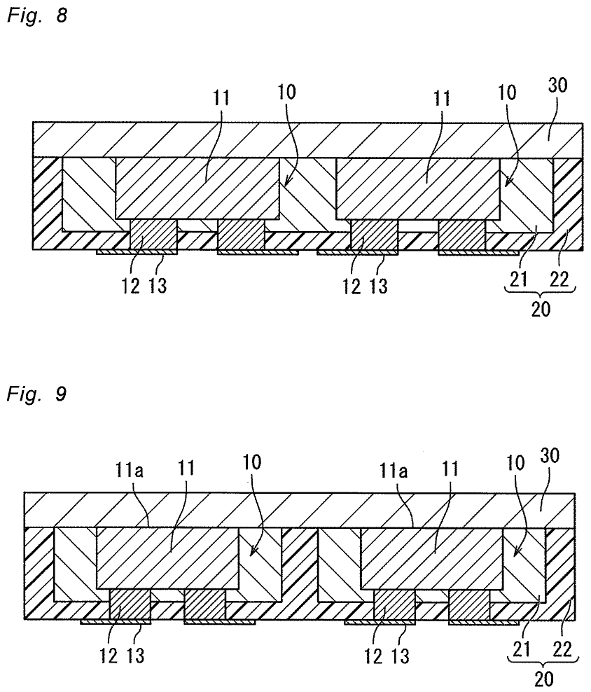

In each of the plurality of light-emitting elements 10, the light-reflective inorganic member 21 may cover the semiconductor structure 11 except for the light-emitting surface 11a of each semiconductor structure 11 and the region where the first electrode 12 is disposed. For example, as illustrated in FIG. 8, the two light-emitting elements 10 may be collectively covered with the light-reflective inorganic member 21. The entire outer surface of the light-reflective inorganic member 21 except for the surface facing the wavelength conversion member 30 may be covered with the light-reflective resin member 22. According to such a covering mode of the light-reflective inorganic member 21, the interval between the light-emitting elements 10 can be reduced as compared with the case in which the plurality of light-emitting devices 1 illustrated in FIGS. 1 to 6 are arranged. This makes it possible to reduce the size of the light-emitting device 1.

As a modified example of the manner of covering the light-emitting elements 10, as illustrated in FIG. 9, the semiconductor structures 11 of two light-emitting elements 10 may be individually covered with the light-reflective inorganic members 21. The light-emitting elements 10 individually covered with the light-reflective inorganic members 21 may be collectively covered with the light-reflective resin member 22 except for the surface of each light-reflective inorganic member 21 facing the wavelength conversion member 30. According to such a covering mode of the light-reflective inorganic member 21, deformation of the light-reflective inorganic member 21 covering the light-emitting element 10 can be reduced.

### FIFTH EMBODIMENT

Next, the light-emitting device 1 according to a fifth embodiment of the present disclosure will be described. The light-emitting device according to the fifth embodiment is different from the invention according to the first embodiment in that a light-transmissive resin member or a light-absorptive resin member is used instead of the light-reflective resin member of the light-emitting device according to the first embodiment. The other configurations are basically the same as those of the light-emitting devices according to the first to fourth embodiments of the present disclosure described above.

### Aspect of Resin Member

The light-transmissive resin member is a member that transmits light. For example, the light-transmissive resin member can transmit the light from the light-emitting element 10 at a transmittance of 60% or more. As an example, a transparent resin can be used. As described above, when the light-transmissive resin member is used instead of the light-reflective resin member of the first embodiment, it is possible to reduce the occurrence of a rapid change in luminance at the boundary between the light-emitting surface of the light-emitting device 1 and the non-light-emitting surface surrounding the light-emitting surface.

As the light-absorbing resin member, a resin that absorbs light (for example, a black resin) can be used. As described above, when the light-absorbing resin member is used instead of the light-reflective resin member of the first embodiment, the luminance difference between the light-emitting surface of the light-emitting device 1 and the non-light-emitting surface surrounding the light-emitting surface is increased, so the light-emitting device 1 with good contrast can be obtained.

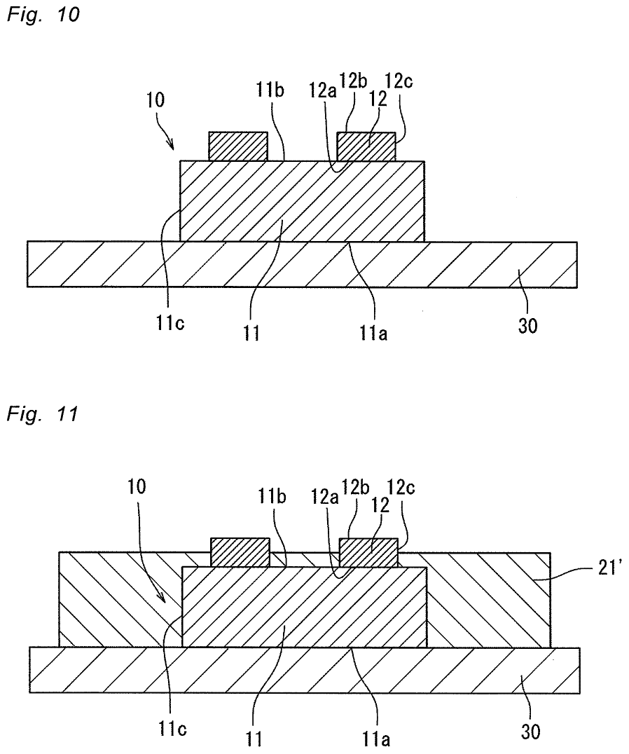

Next, a method of manufacturing a light-emitting device according to the present disclosure will be described in detail with reference to FIGS. 10 to 14. A method of manufacturing a light-emitting device according to the present disclosure includes a “preparing step of preparing a light-emitting element”, a “first covering step”, and a “second covering step”. The method may further include a “step of disposing a wavelength conversion member”, an “electrode exposing step”, and/or a “step of forming a second electrode”. The method will be described below, following each step.

### Step of Preparing Light-emitting Element

First, the light-emitting element 10 is prepared, including: the semiconductor structure 11 having the light-emitting surface 11a and the electrode-forming surface 11b opposite to the light-emitting surface 11a; and the first electrode 12 disposed on the electrode-forming surface 11b, and having the first surface 12a facing the electrode-forming surface 11b, the second surface 12b located on the side opposite to the first surface 12a, and the lateral surface 12c located between the first surface 12a and the second surface 12b. The light-emitting element 10 can be prepared through some or all of the manufacturing steps, such as a step of growing a semiconductor. Alternatively, the light-emitting element 10 can be prepared by purchase or the like.

### Step of Disposing Wavelength Conversion Member

Subsequently, as illustrated in FIG. 10, the prepared light-emitting element 10 is disposed on the wavelength conversion member 30. After an adhesive is applied onto the wavelength conversion member 30, the light-emitting element 10 is disposed on the adhesive, whereby the wavelength conversion member 30 and the light-emitting element 10 are bonded to each other. In the example illustrated in FIG. 10, the adhesive is disposed between the wavelength conversion member 30 and the light-emitting element 10. The adhesive is not illustrated in FIG. 10. As a material of the adhesive, a light-transmitting thermosetting resin material such as an epoxy resin or a silicone resin can be used. The adhesive is applied by, for example, potting or pin transfer. FIGS. 10 to 14 shows an example illustrating a single light-emitting element 10 disposed on the wavelength conversion member 30, but the present invention is not limited to this example, and a plurality of light-emitting devices 1 may be manufactured by disposing a plurality of light-emitting elements 10 on the wavelength conversion member 30 and singulating the plurality of light-emitting elements 10 into individual light-emitting elements 10 in the singulation step described below.

### First Covering Step

The first covering step is a step in which at least the lateral surface of the light-emitting element 10 is covered with the light-reflective inorganic member 21. First, a light-reflective inorganic material 21′ constituting the light-reflective inorganic member 21 is prepared. The light-reflective inorganic material 21′ is prepared by mixing the materials of the filler and the support material. The mixing of the materials of the filler and the support material is performed, for example, by mixing to the extent that a uniform viscosity is obtained, and then defoaming and stirring with a stirring defoaming machine that can stir under reduced pressure. The filler and the support material may be mixed with an alkali solution containing an alkali metal and formed through a step such as heating. In this case, the light-reflective inorganic member 21 contains an alkali metal derived from the alkaline solution. Examples of the alkali metal contained in the alkaline solution include potassium and/or sodium. When the filler and the support material are mixed by the alkaline solution, the filler can be appropriately dispersed in the light-reflective inorganic member 21.

After the light-reflective inorganic material 21′ is prepared, as illustrated in FIG. 11, the light-reflective inorganic material 21′ is applied to at least the lateral surface of the light-emitting element 10. By vibrating the wavelength conversion member 30 during and/or after the application of the light-reflective inorganic material 21′, the light-reflective inorganic material 21′ can be spread over a wide area. As a method of vibrating here, for example, a vibration forming machine or the like is used, and vibration is performed with an excitation force in a range from 500 N to 3000 N. Instead of vibrating the wavelength conversion member 30, the light-reflective inorganic material 21′ may be applied while vibrating a nozzle for supplying the light-reflective inorganic material 21′. Thereafter, the light-reflective inorganic material 21′ is cured by heating to form the light-reflective inorganic member 21 having light reflectivity. The temperature at which the light-reflective inorganic material is heated is, for example, in a range from 150° C. to 250° C. The shape of the light-reflective inorganic material 21′ having the lateral surface as illustrated in FIG. 11 can be achieved by, for example, applying the light-reflective inorganic material 21′ in a state where a guide is disposed around the light-emitting element 10, curing the light-reflective inorganic material 21′, and then removing the guide. The light-reflective inorganic member 21 covering the lateral surface of the wavelength conversion member 30 described in the second embodiment can be formed, for example, by disposing the wavelength conversion member 30 on a support plate (not illustrated), disposing the light-emitting element 10 on the wavelength conversion member 30, and applying the light-reflective inorganic material 21′ on the support plate so as to cover the lateral surface of the wavelength conversion member 30, the lateral surface 11c and the electrode-forming surface 11b of the semiconductor structure 11 of the light-emitting element 10, and the lateral surface 12c of the first electrode 12. At this time, by applying the light-reflective inorganic material 21′ with an appropriate viscosity and in an appropriate amount, the surface of the light-reflective inorganic member 21 opposite to the surface facing the lateral surface of the light-emitting element 10 can be formed as an inclined surface or a curved surface.

In the case in which no light-transmissive member or no wavelength conversion member is disposed on the light-emitting surface 11a of the light-emitting elements 10 as illustrated in FIG. 6, the light-reflective inorganic member 21 covering the lateral surface of the light-emitting element 10 can be formed by disposing the light-emitting element 10 on a support plate (not shown) and applying the light-reflective inorganic material 21′ on the support plate so as to cover the lateral surface 11c and the electrode-forming surface 11b of the semiconductor structure 11 of the light-emitting element 10 and the lateral surface 12c of the first electrode 12.

Here, the light-reflective inorganic material 21′ may be applied so as not to completely cover the first electrode 12. As illustrated in FIG. 5, the electrode-forming surface 11b of the semiconductor structure 11 may be exposed. Such application of the light-reflective inorganic material 21′ can reduce the volume of the light-reflective inorganic member 21 at the electrode-forming surface 11b as described above in the “light-emitting device according to the third embodiment”, and can effectively reduce deformation of the light-reflective inorganic member 21 due to processing (such as grinding).

### Second Covering Step

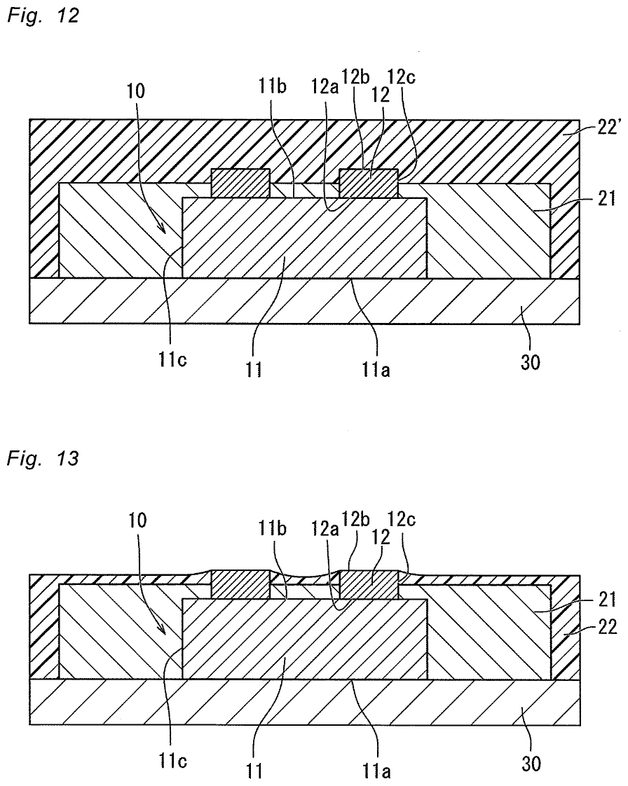

The second covering step is a step of covering the electrode-forming surface 11b with the light-reflective resin member 22 such that the second surface 12b of the first electrode 12 is exposed. First, a light-reflective resin material 22′ constituting the light-reflective resin member 22 is prepared. As an example, a liquid silicone resin is prepared and applied so as to cover the light-reflective inorganic member 21 as illustrated in FIG. 12. In the example illustrated in FIG. 12, the light-reflective resin material 22′ completely covers the semiconductor structure 11, the light-reflective inorganic member 21, and the first electrode 12. The light-reflective resin material 22′ does not have to completely cover the semiconductor structure 11, the light-reflective inorganic member 21, and the first electrode 12. For example, the light-reflective resin material 22′ does not have to cover a part of the first electrode 12. The light-reflective inorganic member 21 can be impregnated with a part of the light-reflective resin material 22′.

### Electrode Exposing Step

The second covering step may include an electrode exposing step of exposing the second surface 12b of the first electrode 12 from the light-reflective resin member 22. As illustrated in FIG. 13, the light-reflective resin material 22′ is ground to expose the second surface 12b of the first electrode 12 of the light-emitting element 10.

The light-reflective inorganic member 21 is harder than an organic material, but is brittle when processed. In the electrode exposing step, as illustrated in FIG. 13, the light-reflective inorganic member 21 is covered with the light-reflective resin member 22, which is an organic material, so deformation of the light-reflective inorganic member 21 due to processing can be reduced.

Here, when the light-reflective resin member 22 is ground, the light-reflective resin member 22 is pressed and deformed by the grindstone, whereas the first electrode 12 having higher rigidity than that of the light-reflective resin member 22 is less likely to be pressed and deformed by the grindstone. Therefore, the thickness of the light-reflective resin member 22 after the electrode exposing step may increase toward the first electrode 12. Therefore, the heat resistance of a portion in the vicinity of the first electrode 12 to which heat is relatively subjected is secured.

### Second Electrode Forming Step

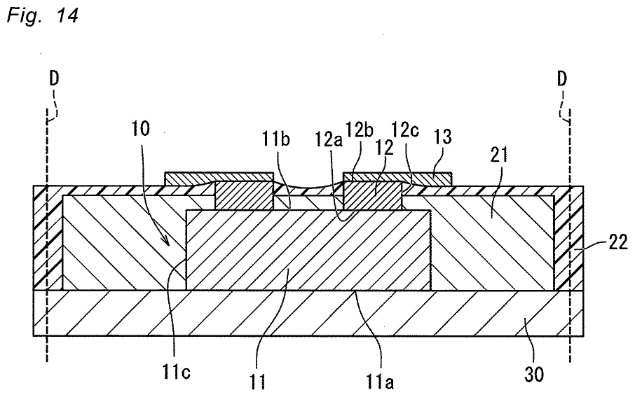

The second electrode forming step is a step of forming the second electrode 13 that is bonded to the second surface 12b of the first electrode 12 and extends from the second surface 12b to the outer surface of the light-reflective resin member 22. As illustrated in FIG. 14, the second electrode 13 is formed in order to suppress corrosion and oxidation of the exposed first electrode 12. The second electrode 13 can be formed by, for example, sputtering, vapor deposition, an atomic layer deposition (ALD) method, a metal organic chemical vapor deposition (MOCVD) method, a plasma-enhanced chemical vapor deposition (PECVD) method, an atmospheric pressure plasma deposition method, or the like. In the case of manufacturing the plurality of light-emitting devices 1, after the second electrode 13 is formed, the light-emitting device 1 is manufactured by cutting at a predetermined cutting position (for example, a broken line D in FIG. 14) to singulate. In the step of singulation, as illustrated in FIG. 14, because the light-reflective inorganic member 21 is covered with the light-reflective resin member 22 that is an organic material, deformation of the light-reflective inorganic member 21 can be reduced.

In addition, by cutting at a position including the light-reflective inorganic member 21 and the light-reflective resin member 22 in the thickness direction of the light-reflective member 20, it is possible to achieve a structure in which the outer lateral surface of the light-emitting device 1 is constituted by the light-reflective inorganic member 21 and the light-reflective resin member 22 as illustrated in FIG. 5.

As described above, the method of manufacturing the light-emitting device 1 according to the present disclosure can manufacture a light-emitting device that includes the light-reflective inorganic member 21 to improve heat resistance, and includes the light-reflective resin member 22 to reduce deformation of the light-reflective inorganic member 21 due to processing during manufacture of the light-emitting device 1.

In the method of manufacturing the light-emitting device described above, the step of covering the electrode-forming surface 11b with the light-reflective resin member 22 such that the second surface 12b of the first electrode 12 is exposed has been described as the second covering step. Instead of the light-reflective resin member, the resin member (for example, a light-transmissive resin member or a resin member that absorbs light) described in the fifth embodiment may be used.

The embodiments disclosed this time are illustrative in all respects and are not intended to be the basis of limiting interpretation. Accordingly, the technical scope of the present disclosure is not construed solely by the embodiment described above but is defined based on the description of the scope of claims. In addition, the technical scope of the present disclosure includes all variations within the meaning and scope equivalent to the scope of claims.

What is claimed is:

1. A light-emitting device comprising:
a light-emitting element comprising:
a semiconductor structure having a light-emitting surface, an electrode-forming surface located on a side opposite to the light-emitting surface, and a lateral surface located between the light-emitting surface and the electrode-forming surface, and
a first electrode disposed on the electrode-forming surface and having a first surface facing the electrode-forming surface, a second surface located on a side opposite to the first surface, and a lateral surface located between the first surface and the second surface; and
a light-reflective member covering the light-emitting element except for the light-emitting surface and the second surface, wherein
the light-reflective member comprises:
a light-reflective inorganic member covering at least the lateral surface of the semiconductor structure; and
a light-reflective resin member covering the lateral surface of the first electrode, and the light-reflective inorganic member.

2. A light-emitting device comprising:
a light-emitting element comprising:
a semiconductor structure having a light-emitting surface, an electrode-forming surface located on a side opposite to the light-emitting surface, and a lateral surface located between the light-emitting surface and the electrode-forming surface, and
a first electrode disposed on the electrode-forming surface and having a first surface facing the electrode-forming surface, a second surface located on a side opposite to the first surface, and a lateral surface located between the first surface and the second surface;
a light-reflective inorganic member covering at least the lateral surface of the semiconductor structure, and covering the light-emitting element except for the light-emitting surface and the second surface; and
a resin member covering the light-reflective inorganic member and the lateral surface of the first electrode.

3. The light-emitting device according to claim 1, further comprising a wavelength conversion member disposed on the light-emitting surface of the light-emitting element.

4. The light-emitting device according to claim 1, wherein
an outer surface of the light-reflective inorganic member is entirely covered with the light-reflective resin member.

5. The light-emitting device according to claim 2, wherein
an outer surface of the light-reflective inorganic member is entirely covered with the resin member.

6. The light-emitting device according to claim 1, wherein
a surface of the light-reflective inorganic member opposite to a surface facing a lateral surface of the light-emitting element is inclined or curved, and a distance from the lateral surface of the light-emitting element in a lateral direction increases toward the light-emitting surface.

7. The light-emitting device according to claim 1, wherein
the light-reflective resin member is included in a portion of an outer lateral surface of the light-emitting device.

8. The light-emitting device according to claim 2, wherein
the resin member is included in a portion of an outer lateral surface of the light-emitting device.

9. The light-emitting device according to claim 3, wherein
a lateral surface of the wavelength conversion member is covered with the light-reflective inorganic member.

10. The light-emitting device according to claim 1, wherein
the electrode-forming surface is covered with the light-reflective inorganic member.

11. The light-emitting device according to claim 1, wherein
the electrode-forming surface is covered with the light-reflective resin member.

12. The light-emitting device according to claim 2, wherein
the electrode-forming surface is covered with the resin member.

13. The light-emitting device according to claim 1, wherein
the light-emitting device includes a second electrode bonded to the second surface, and
the second electrode extends from the second surface to an outer surface of the light-reflective resin member.

14. The light-emitting device according to claim 2, wherein
the light-emitting device includes a second electrode bonded to the second surface, and
the second electrode extends from the second surface to an outer surface of the resin member.

15. A method of manufacturing a light-emitting device, the method comprising:
a preparing step of preparing a light-emitting element including,
a semiconductor structure having a light-emitting surface and an electrode-forming surface located on a side opposite to the light-emitting surface, and
a first electrode disposed on the electrode-forming surface and having a first surface facing the electrode-forming surface, a second surface located on a side opposite to the first surface, and a lateral surface located between the first surface and the second surface;
a first covering step of covering a lateral surface of the light-emitting element with a light-reflective inorganic member; and
a second covering step of covering the electrode-forming surface with a light-reflective resin member to expose the second surface.

16. A method of manufacturing a light-emitting device, the method comprising:
a preparing step of preparing a light-emitting element including,
a semiconductor structure having a light-emitting surface and an electrode-forming surface located on a side opposite to the light-emitting surface, and
a first electrode disposed on the electrode-forming surface and having a first surface facing the electrode-forming surface, a second surface located on a side opposite to the first surface, and a lateral surface located between the first surface and the second surface;
a first covering step of covering a lateral surface of the light-emitting element with a light-reflective inorganic member; and
a second covering step of covering the electrode-forming surface with a resin member to expose the second surface.

17. The method of manufacturing a light-emitting device according to claim 15, comprising, between the preparing step and the first covering step, a step of disposing a wavelength conversion member on a light-emitting surface of the light-emitting element.

18. The method of manufacturing a light-emitting device according to claim 15, wherein
the second covering step includes an electrode exposing step of exposing the second surface from the light-reflective resin member.

19. The method of manufacturing a light-emitting device according to claim 16, wherein
the second covering step includes an electrode exposing step of exposing the second surface from the resin member.

20. The method of manufacturing a light-emitting device according to claim 15, further comprising a step of forming a second electrode bonded to the second surface and extending from the second surface to an outer surface of the light-reflective resin member.

21. The method of manufacturing a light-emitting device according to claim 16, further comprising a step of forming a second electrode bonded to the second surface and extending from the second surface to an outer surface of the resin member.
